(19) United States
(12) Patent Application Publication
(10) Pub. No.: US 2013/0063923 A1
(43) Pub. Date: Mar. 14, 2013

(54) DISPLAY DEVICE

(71) Applicant: Tatsuro Kuroda, Osaka (JP)

(72) Inventor: Tatsuro Kuroda, Osaka (JP)

(73) Assignee: SHARP KABUSHIKI KAISHA, Osaka (JP)

(21) Appl. No.: 13/696,675

(22) PCT Filed: Jan. 27, 2011
(86) PCT No.: PCT/JP2011/051568

§ 371 Date: Nov. 7, 2012

(30) Foreign Application Priority Data
May 28, 2010 (JP) 2010-123259

(51) Int. Cl. H05K 9/00

(52) U.S. Cl. 361/818

(57) ABSTRACT

Disclosed is a display device wherein moving of a display panel in the planar direction is suppressed, while reducing EMI. The liquid crystal display device is provided with the liquid crystal display panel, and a holding member, which holds the end portion of the liquid crystal display panel. The holding member includes: a front side holding section, which is disposed on the front side of the liquid crystal display panel; a rear side holding section, which is disposed on the rear side of the liquid crystal display panel; and regulating sections, which are disposed on the side of the liquid crystal display panel, and which regulate moving of the liquid crystal display panel in the planar direction of the liquid crystal display panel. The front side holding section has a function of blocking electromagnetic waves.

### TECHNICAL FIELD

The present invention relates to a display device, more particularly, to a display device that includes a hold member which holds an edge portion of a display panel.

### BACKGROUND ART

Conventionally, a display device is known, which includes a hold member that holds an edge portion of a display panel. FIG. 18 is a sectional view showing a structure of a display device as a conventional example that includes a hold member which holds an edge portion of a display panel. FIG. 19 is an enlarged sectional view showing the structure of the display device as the conventional example shown in FIG. 18.

The display device 100 as the conventional example, as shown in FIG. 18, includes: a display panel 1002; a hold member 1010 that holds an edge portion of the display panel 1002; a backlight chassis 1003 and a bezel 1004 that sandwich the hold member 1010; and a plurality of light sources 1005 that are housed in a recess portion 1003a of the backlight chassis 1003.

The hold member 1010, as shown in FIG. 19, includes: a push member (front surface side hold portion) 1011 that pushes a front surface of the display panel 1002; and a support member (rear surface side hold portion) 1012 that is biased to a rear surface of the display panel 1002. Besides, the hold member 1010 (the push member 1011 and the support member 1012) is formed of a member such as non-electroconductive rubber, resin or the like that has a relatively large friction coefficient, and is able to hold the display panel 1002.

The bezel 1004 is formed of, for example, metal, and the backlight chassis 1003 is formed of, for example, resin.

Here, a display device, which includes a hold member formed of a non-electroconductive member like the display device 1001 as the conventional example, is disclosed in a patent document 1, for example.

In the meantime, in recent years, because of high definition of a display device, the number of wirings of a display panel is increasing. Because of this, electromagnetic waves occurring from the display panel increase, accordingly, it is requested to take anti-EMI (Electro Magnetic Interference) measures.

However, in the display device 1001 as the conventional example, the push member 1011 disposed on the display panel 1002 is formed of a non-electroconductive member, accordingly, it is hard to block the electromagnetic waves occurring from the display panel 1002. Because of this, there is a disadvantage that it is hard to reduce EMI.

Accordingly, to improve the disadvantage, a method is conceivable, in which the push member 1011 is replaced with a gasket or the like that uses a metal material, for example.

### CITATION LIST

### Patent Literature

PLT1: JP-A-1995-281184

### SUMMARY OF INVENTION

### Technical Problem

However, in a case where the push member is formed of a gasket or the like that uses a metal material, the friction coefficient of the push member becomes small compared with the case where the push member is formed of a member such as rubber, resin or the like. Because of this, there is a problem that because of vibration and the like, there is a case where the display panel moves (positional deviation or coming-off) in a surface direction.

The present invention has been made to deal with the above problems, and it is an object of the present invention to provide a display device that is able to reduce EMI and alleviate a display panel moving in a surface direction.

### Solution to Problem

To achieve the above object, a display device according to one aspect of the present invention includes: a display panel; and a hold member that holds an edge portion of the display panel; wherein the hold member includes: a front surface side hold portion that is disposed on a front surface side of the display panel; a rear surface side hold portion that is disposed on a rear surface side of the display panel; and a limit portion that is disposed on a side of the display panel and limits the display panel moving in a surface direction of the display panel, and at least the front surface side hold portion has a function to block an electromagnetic wave.

In the display device according to the one aspect, as described above, by providing the hold member with the front surface side hold portion that has the function to block the electromagnetic wave, it is possible to block the electromagnetic wave occurring from the display panel by means of the hold member. According to this, it is possible to alleviate the electromagnetic wave, which occurs from the display panel, leaking to outside, accordingly, it is possible to reduce EMI. Besides, it is possible to block the electromagnetic wave occurring from the display panel at a position near the occurrence source (the display panel), accordingly, it is possible to effectively block the electromagnetic wave.

Besides, in the display device according to the one aspect, as described above, by providing the hold member with the limit portion that is disposed on the side of the display panel and limits the display panel moving in the surface direction of the display panel, even in a case where friction coefficients of the front surface side hold portion and the rear surface side hold portion are small, it is possible to limit the display panel moving in the surface direction. In other words, it is possible to alleviate the display panel positionally deviating or coming off in the surface direction.

In the display device according to the one aspect, preferably, the limit portion also has the function to block the electromagnetic wave. According to this structure, it is possible to more alleviate the electromagnetic wave, which occurs from the display panel, leaking to the outside, accordingly, it is possible to more reduce EMI.

In the display device according to the one aspect, preferably, the rear surface side hold portion also has the function to block the electromagnetic wave. According to this structure, it is possible to more alleviate the electromagnetic wave, which occurs from the display panel, leaking to the outside, accordingly, it is possible to more reduce EMI.

In the display device according to the one aspect, preferably, the hold member includes an electroconductive cloth. According to this structure, it is possible to easily block the electromagnetic wave.

In the display device according to the one aspect, preferably, the limit portion is integrally formed with the front surface side hold portion. According to this structure, it is possible to alleviate the number of components of the hold member increasing and it is possible to easily perform assembly and disassembly of the display device. Besides, it is possible to easily alleviate the limit portion moving with respect to the front surface side hold portion.

In the display device according to the one aspect, preferably, the hold member includes a sponge member and an electroconductive cloth that covers the sponge member. According to this structure, it is possible to easily hold the display panel by means of restitution force of the sponge member. Besides, it is possible to easily block the electromagnetic wave by means of the electroconductive cloth.

In the display device in which the hold member includes the sponge member and the electroconductive cloth, preferably, the sponge member includes a first sponge member and a second sponge member that has an elastic modulus higher than the first sponge member; the front surface side hold portion is formed of the first sponge member; and the limit portion is formed of the second sponge member. According to this structure, it is possible to hold the display panel by means of the front surface side hold portion (the first sponge member) and limit the display panel moving in the surface direction by means of the limit portion (the second sponge member).

The display device according to the one aspect preferably includes a slide stopping member that is disposed between at least one of the front surface side hold portion and the rear surface side hold portion and the display panel, and alleviates the display panel moving in the surface direction. According to this structure, it is possible to more alleviate the display panel moving in the surface direction.

In the display device that includes the slide stopping member, preferably, the slide stopping member is formed of PORON (registered trademark). The PORON (registered trademark) has a relatively large friction coefficient, accordingly, by forming the slide stopping member by means of the PORON (registered trademark), it is possible to easily alleviate the display panel moving in the surface direction.

The display device according to the one aspect preferably includes a fix member that fixes at least one of the front surface side hold portion and the rear surface side hold portion; at least one of the front surface side hold portion and the rear surface side hold portion is provided with a first engagement portion; and the fix member is provided with a second engagement portion that engages with the first engagement portion, and alleviates the hold member moving in the surface direction. According to this structure, it is possible to alleviate the hold member moving in the surface direction of the display panel, accordingly, it is possible to easily alleviate the display panel moving in the surface direction by means of the hold member.

### Advantageous Effects of Invention

As described above, according to the present invention, it is possible to easily obtain a display device that is able to reduce EMI and alleviate a display panel moving in a surface direction.

### BRIEF DESCRIPTION OF DRAWINGS

FIG. 1 is a sectional view showing a structure of a liquid crystal display device according to a first embodiment of the present invention.

FIG. 2 is an enlarged sectional view showing the structure of the liquid crystal display device according to the first embodiment of the present invention shown in FIG. 1.

FIG. 3 is an enlarged view showing a structure of a push member of the liquid crystal display device according to the first embodiment of the present invention shown in FIG. 1.

FIG. 4 is an enlarged sectional view showing the structure of the push member of the liquid crystal display device according to the first embodiment of the present invention shown in FIG. 1.

FIG. 5 is an enlarged view showing a structure of a support member of the liquid crystal display device according to the first embodiment of the present invention shown in FIG. 1.

FIG. 6 is an enlarged sectional view showing the structure of the support member of the liquid crystal display device according to the first embodiment of the present invention shown in FIG. 1.

FIG. 7 is an enlarged view for describing a structure of a slide stopping member of a liquid crystal display device according to a second embodiment of the present invention.

FIG. 8 is an enlarged view for describing a structure of a hold member of a liquid crystal display device according to a third embodiment of the present invention.

FIG. 9 is an enlarged view for describing a structure of a hold member of a liquid crystal display device according to a fourth embodiment of the present invention.

FIG. 10 is an enlarged sectional view for describing the structure of the hold member according to the fourth embodiment of the present invention shown in FIG. 9.

FIG. 11 is an enlarged view for describing the structure of the hold member according to the fourth embodiment of the present invention shown in FIG. 9.

FIG. 12 is an enlarged view for describing the structure of the hold member according to the fourth embodiment of the present invention shown in FIG. 9.

FIG. 13 is an enlarged view for describing a structure of a push member of a liquid crystal display device according to a fifth embodiment of the present invention.

FIG. 14 is an enlarged view for describing a structure of a hold member of a liquid crystal display device according to a sixth embodiment of the present invention.

FIG. 15 is an enlarged view for describing a structure of a hold member of a liquid crystal display device according to a seventh embodiment of the present invention.

FIG. 16 is an enlarged view showing a structure of a hold member according to a first modification example of the present invention.

FIG. 17 is an enlarged view showing a structure of a hold member according to a second modification example of the present invention.

FIG. 18 is a sectional view showing a structure of a display device as a conventional example.

FIG. 19 is an enlarged sectional view showing the structure of the display device as the conventional example shown in FIG. 18.

### DESCRIPTION OF EMBODIMENTS

Hereinafter, embodiments of the present invention are described with reference to the drawings. Here, for the sake of easy understanding, there is a case where hatching is not applied to even a sectional view.

### First Embodiment

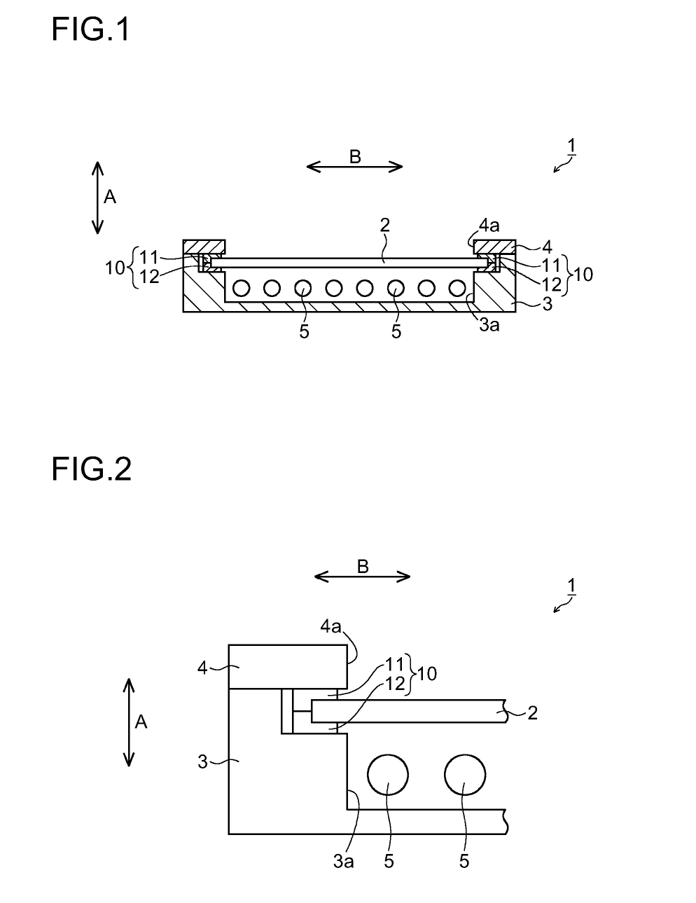

With reference to FIG. 1 to FIG. 6, a structure of a liquid crystal display device 1 according to a first embodiment of the present invention is described.

The liquid crystal display device 1 according to the first embodiment of the present invention composes a liquid crystal television receiver (not shown) and the like, for example. Besides, the liquid crystal display device 1 is, as shown in FIG. 1, composed of: a liquid crystal display panel 2; a hold member 10 that holds an edge portion of the liquid crystal display panel 2; a backlight chassis 3 and a bezel 4 that sandwich the hold member 10; and a plurality of light sources 5 that are housed in a recess portion 3a of the backlight chassis 3. And, a backlight device of direct type is composed of the backlight chassis 3, the plurality of light sources 5 and the like. Here, the liquid crystal display device 1 is an example of a “display device” of the present invention, and the liquid crystal display panel 2 is an example of a “display panel” of the present invention.

The liquid crystal display panel 2 includes two glass boards that sandwich a not-shown liquid crystal layer. Besides, the liquid crystal display panel 2 is provided with a plurality of wirings (not shown). The liquid crystal display panel 2 is illuminated by the light source 5 to function as a display panel.

The hold member 10 is disposed on four edge portions (four edges) of the liquid crystal display panel 2. Besides, the hold member 10 is formed into an elongated shape along edge portions of the liquid crystal display panel 2.

Besides, the hold member 10, as shown in FIG. 2, is composed of: a push member 11 that pushes a front surface (upper surface) of the edge portion of the liquid crystal display panel 2; and a support member 12 that is biased to a rear surface (lower surface) of the edge portion of the liquid crystal display panel 2.

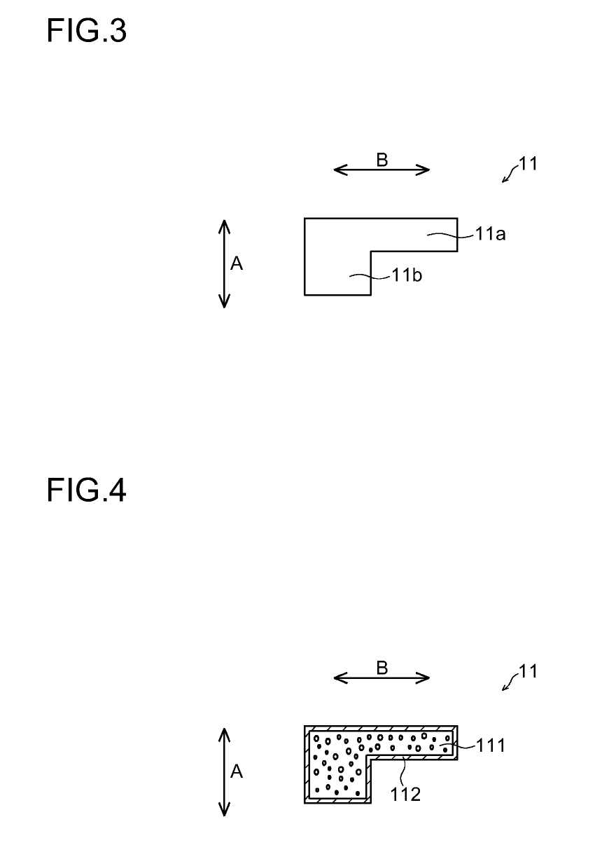

Here, in the first embodiment, the push member 11, as shown in FIG. 3, is formed into a step shape (L shape) when viewed in section, and includes: a front surface side hold portion 11a that pushes a front surface of the liquid crystal display panel 2 (see FIG. 2); and a limit portion 11b that is disposed on a side of the liquid crystal display panel 2. In other words, the front surface side hold portion 11a and the limit portion 11b are formed integrally with each other.

Besides, the push member 11 is formed of a gasket, for example. Specifically, the push member 11, as shown in FIG. 4, is formed of: an L-shaped sponge member 111 that is used as a core member; and an electroconductive cloth 112 that wraps the sponge member 111.

The sponge member 111 is formed of a foam material such as polyurethane foam and the like, for example.

The electroconductive cloth 112 is formed of, for example, an electroconductive fiber that is obtained by applying metal plating to a polyester woven textile, and has a function to block an electromagnetic wave. Because of this, the front surface side hold portion 11a and the limit portion 11b (see FIG. 3) of the push member 11 have the function to block the electromagnetic wave.

Here, an adhesive layer (not shown) may be disposed on a front surface (upper surface) of the electroconductive cloth 112, and the push member 11 may be bonded to the bezel 4 (see FIG. 2) by means of the adhesive layer.

Besides, in the first embodiment, the support member 12, as shown in FIG. 5, is formed into a step shape (L shape) when viewed in section, and includes: a rear surface side hold portion 12a that supports a rear surface of the liquid crystal display panel 2 (see FIG. 2); and a limit portion 12b that is disposed on the side of the liquid crystal display panel 2. In other words, the rear surface side hold portion 12a and the limit portion 12b are formed integrally with each other.

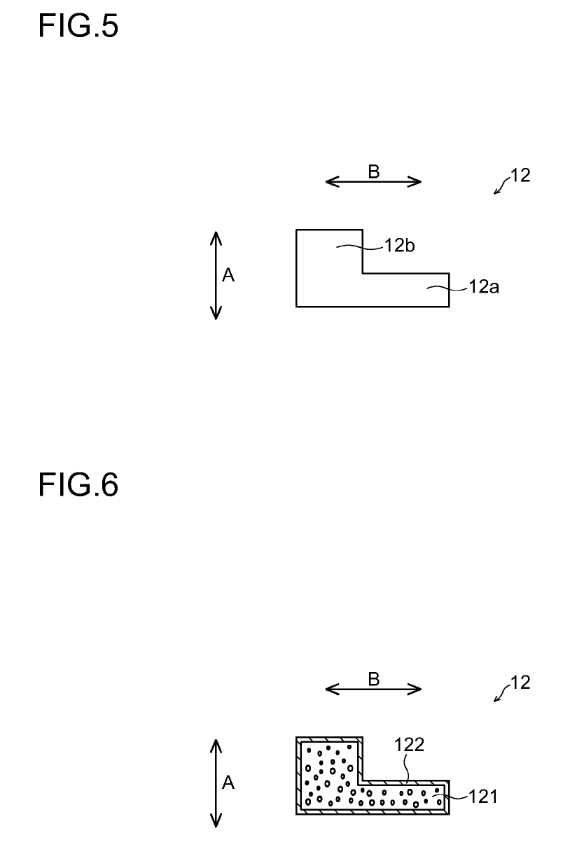

Besides, the support member 12 is formed of a gasket, for example. Specifically, the support member 12, as shown in FIG. 6, is formed of: an L-shaped sponge member 121 that is used as a core member; and an electroconductive cloth 122 that wraps the sponge member 121.

The sponge member 121 is formed of a foam material such as polyurethane foam and the like, for example.

The electroconductive cloth 122 is formed of, for example, an electroconductive fiber that is obtained by applying metal plating to a polyester woven textile, and has the function to block the electromagnetic wave. Because of this, the rear surface side hold portion 12a and the limit portion 12b (see FIG. 5) of the support member 12 have the function to block the electromagnetic wave.

Here, the support member 12 may be formed of a member such as non-electroconductive rubber, resin or the like without using the sponge member 121 and the electroconductive cloth 122. In this case, the support member 12 may be formed of polyurethane foam such as the PORON (registered trademark) and the like, for example.

Besides, an adhesive layer (not shown) may be disposed on a rear surface (lower surface) of the support member 12, and the support member 12 may be bonded to the backlight chassis 3 (see FIG. 2) by means of the adhesive layer.

Besides, as shown in FIG. 2, the hold member 10 (the push member 11 and the support member 12) is sandwiched by the bezel 4 and the backlight chassis 3, thereby holding the liquid crystal display panel 2. And, by means of the front surface side hold portion 11a (see FIG. 3) of the push member 11 and the rear surface side hold portion 12a (see FIG. 3) of the support member 12, movement of the liquid crystal display panel 2 in a thickness direction (A direction) is limited (alleviated). Besides, by means of the limit portion 11b of the push member 11 and the limit portion 12b of the support member 12, movement of the liquid crystal display panel 2 in a surface direction (B direction that meets the A direction at right angles) is limited.

The backlight chassis 3 is formed of resin, for example. Besides, the backlight chassis 3 is provided with the recess portion 3a that houses the plurality of light sources 5. Here, in the recess portion 3a, between the light source 5 and the liquid crystal display panel 2, optical sheets (not shown) such as a prism sheet, a lens sheet and the like may be disposed, and a reflection sheet (not shown) may be disposed at a position opposite to a rear surface of the light source 5.

Besides, the light source 5 is formed of a fluorescent lamp, for example. Here, the light source 5 may be formed of, for example, an LED (Light Emitting Diode) and the like other than the fluorescent lamp.

The bezel 4 is formed of a metal plate (metal), for example. Besides, the bezel 4 is provided with an opening portion 4a at a portion that corresponds to a display region of the liquid crystal display panel 2.

In the first embodiment, as described above, by providing the hold member 10 with: the push member 11 (the front surface side hold portion 11a and the limit portion 11b) having the function to block the electromagnetic wave; and the support member 12 (the rear surface side hold portion 12a and the limit portion 12b), it is possible to block the electromagnetic wave occurring from the liquid crystal display panel 2 by means of the hold member 10. According to this, it is possible to alleviate the electromagnetic wave, which occurs from the liquid crystal display panel 2, leaking to outside, accordingly, it is possible to reduce EMI. Besides, it is possible to block the electromagnetic wave occurring from the liquid crystal display panel 2 at a position near the occurrence source (the liquid crystal display panel 2), accordingly, it is possible to effectively block the electromagnetic wave.

Besides, the front surface side hold portion 11a (the push member 11) is disposed between the liquid crystal display panel 2 and the bezel 4, accordingly, it is possible to alleviate the electromagnetic wave, which occurs from the liquid crystal display panel 2, leaking to the outside from a gap between the liquid crystal display panel 2 and the bezel 4.

Besides, in the first embodiment, as described above, by providing the hold member 10 with the limit portions 11b and 12b that are disposed on the side of the liquid crystal display panel 2 and limit the liquid crystal display panel 2 moving in the surface direction (the B direction), even in a case where friction coefficients of the push member 11 (the front surface side hold portion 11a) and the support member 12 (the rear surface side hold portion 12a) are small, it is possible to limit the liquid crystal display panel 2 moving in the surface direction (the B direction). In other words, it is possible to alleviate the liquid crystal display panel 2 positionally deviating and coming off in the surface direction (the B direction).

Besides, in the first embodiment, as described above, by forming the limit portion 11b integrally with the front surface side hold portion 11a, it is possible to alleviate the number of components of the hold member 10 (the push member 11) increasing, and it is possible to easily perform assembly and disassembly of the liquid crystal display device 1. Besides, it is possible to easily alleviate the limit portion 11b moving with respect to the front surface side hold portion 11a.

Likewise, by forming the limit portion 12b integrally with the rear surface side hold portion 12a, it is possible to alleviate the number of components of the hold member 10 (the support member 12) increasing, and it is possible to easily perform the assembly and the disassembly of the liquid crystal display device 1. Besides, it is possible to easily alleviate the limit portion 12b moving with respect to the rear surface side hold portion 12a.

Besides, in the first embodiment, as described above, by forming the push member 11 (the front surface side hold portion 11a) by means of the sponge member 111 and the electroconductive cloth 112 that wraps the sponge member 111, it is possible to easily hold the liquid crystal display panel 2 by means of restitution force of the sponge member 111. Besides, it is possible to easily block the electromagnetic wave by means of the electroconductive cloth 112.

### Second Embodiment

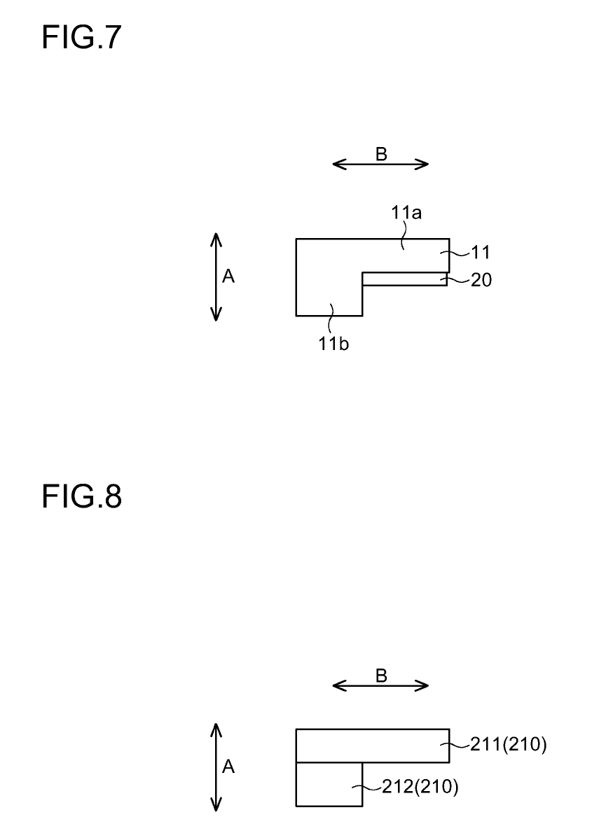

In this second embodiment, as shown in FIG. 7, unlike the first embodiment, a slide stopping member 20 is disposed on a rear surface of the front surface side hold portion 11a of the push member 11. In other words, the slide stopping member 20 is disposed between the front surface side hold portion 11a of the push member 11 and the liquid crystal display panel 2.

The slide stopping member 20 is formed of, for example, polyurethane foam such as the PORON (registered trademark) and the like, and has a friction coefficient larger than the push member 11 (the hold member 10).

Here, the slide stopping member 20 may be bonded to the push member 11 by means of an adhesive layer (not shown).

The other structures of the second embodiment are the same as the first embodiment.

In the second embodiment, as described above, by disposing the slide stopping member 20, which alleviates the liquid crystal display panel 2 moving in the surface direction (the B direction), between the front surface side hold portion 11a and the liquid crystal display panel 2, it is possible to more alleviate the liquid crystal display panel 2 moving in the surface direction (the B direction).

Besides, in the second embodiment, as described above, by forming the slide stopping member 20 by means of the PORON (registered trademark) and forming the slide stopping member to have the friction coefficient larger than the push member 11 (the hold member 10), it is possible to easily alleviate the liquid crystal display panel 2 moving in the surface direction (the B direction).

Here, the other effects of the second embodiment are the same as the first embodiment.

### Third Embodiment

In this third embodiment, with reference to FIG. 8, a case is described, where unlike the first and second embodiments, a push member 211 and a limit member 212 are formed separately from each other.

In the third embodiment, as shown in FIG. 8, a hold member 210 includes: the push member 211 that is disposed on the front surface side of the liquid crystal display panel 2; and the limit member 212 that is disposed on the side of the liquid crystal display panel 2. The push member 211 and the limit member 212 are formed separately from each other unlike the first and second embodiments. Here, the push member 211 is an example of the “front surface side hold portion” of the present invention, and the limit member 212 is an example of the “limit portion” of the present invention.

Besides, the push member 211 and the limit member 212 are formed of a gasket, for example. Besides, each of the push member 211 and the limit member 212 is formed of: a sponge member (not shown) that is used as a core member; and an electroconductive cloth (not shown) that wraps the sponge member. Because of this, the push member 211 and the limit member 212 have the function to block the electromagnetic wave.

Here, an adhesive layer (not shown) may be disposed on a front surface (upper surface) of the limit member 212, and the limit member 212 may be bonded to the push member 211 by means of the adhesive layer.

The other structures of the third embodiment are the same as the first and second embodiments.

In the third embodiment, as described above, by forming the push member 211 and the limit member 212 separately from each other, unlike the first and second embodiments, it is not necessary to form the sponge member into a step shape (L shape), accordingly, it is possible to easily produce the hold member 210 (the push member 211 and the limit member 212).

Here, the other effects of the third embodiment are the same as the first and second embodiments.

### Fourth Embodiment

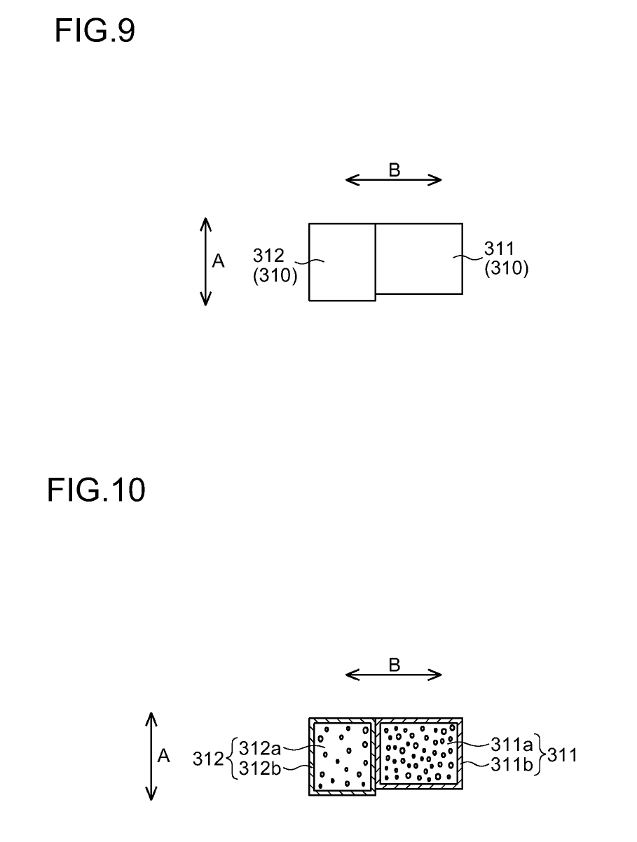

In this fourth embodiment, with reference to FIG. 9 to FIG. 12, a case is described, where unlike the first to third embodiments, a push member 311 and a limit member 312 are formed separately from each other and formed to have elastic moduli different from each other.

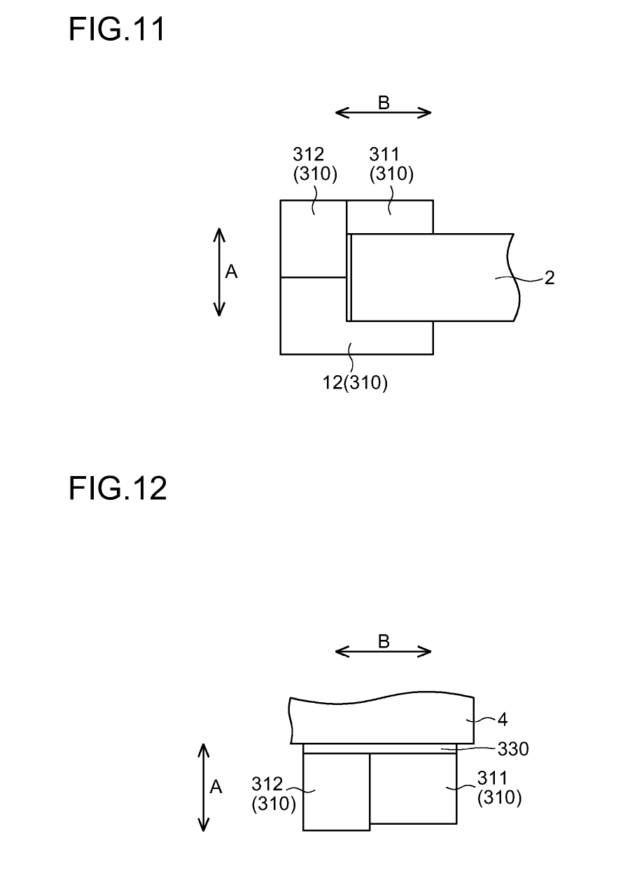

In the fourth embodiment, as shown in FIG. 9, a hold member 310 is composed of: the push member 311 that is disposed on the front surface side of the liquid crystal display panel 2; the limit member 312 that is disposed on the side of the liquid crystal display panel 2; and the support member 12 (see FIG. 11). The push member 311 and the limit member 312 are formed separately from each other like the third embodiment. Here, in the fourth embodiment, the push member 311 and the limit member 312 are disposed adjacently to each other in the B direction. Besides, the push member 311 is an example of the “front surface side hold portion” of the present invention, and the limit member 312 is an example of the “limit portion” of the present invention.

Besides, the push member 311 and the limit member 312 are formed of a gasket, for example. Specifically, as shown in FIG. 10, the push member 311 is formed of: a sponge member 311a; and an electroconductive cloth 311b that wraps the sponge member 311a. Besides, the limit member 312 is formed of: a sponge member 312a; and an electroconductive cloth 312b that wraps the sponge member 312a. Because of this, the push member 311 and the limit member 312 have the function to block the electromagnetic wave. Here, the sponge member 311a is an example of a “first sponge member” of the present invention, and the sponge member 312a is an example of a “second sponge member” of the present invention.

Here, in the fourth embodiment, the sponge member 312a of the limit member 312 has an elastic modulus higher than the sponge member 311a of the push member 311. Conversely, the sponge member 311a of the push member 311 has an elastic modulus lower than the sponge member 312a of the limit member 312.

Because of this, as shown in FIG. 11, in a state where the liquid crystal display panel 2 is sandwiched by mean of the push member 311 and the support member 12, the push member 311 is compressed. And, the liquid crystal display panel 2 is held by means of restitution force of the push member 311.

Besides, the sponge member 312a (see FIG. 3) of the limit member 312 has the elastic modulus higher than the sponge member 311a (see FIG. 3) of the push member 311, accordingly, in a case where the liquid crystal display panel 2 tries to move in the surface direction (the B direction) thanks to vibration and the like, it is possible to alleviate the limit member 312 being compressed. In other words, it is possible to limit the liquid crystal display panel 2 moving in the surface direction (the B direction).

Besides, in the fourth embodiment, to form the sponge member 312a (see FIG. 10) of the limit member 312 to have the elastic modulus higher than the sponge member 311a (see FIG. 10) of the push member 311, the sponge member 312a of the limit member 312 is formed at an expansion ratio smaller than the sponge member 312a of the limit member 312.

Here, as shown in FIG. 12, an adhesive layer 330 may be disposed on a front surface (upper surface) of the push member 311 and the limit member 312, and the push member 311 and the limit member 312 may be bonded to the bezel 4 by means of the adhesive layer 330.

The other structures and effects of the fourth embodiment are the same as the first to third embodiments.

### Fifth Embodiment

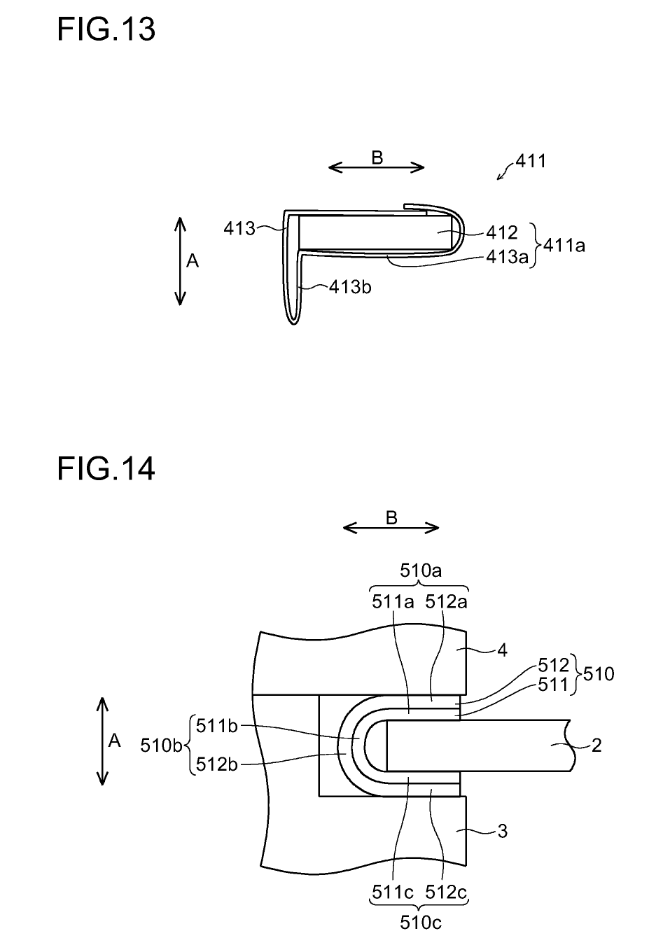

In this fifth embodiment, with reference to FIG. 13, a case is described, where unlike the first to fourth embodiments, a limit portion 413b is formed of an electroconductive cloth 413.

In the fifth embodiment, as shown in FIG. 13, a push member 411 is formed of: a sponge member 412 having a flat plate shape; and an electroconductive cloth 413 that wraps the sponge member 412.

The sponge member 412 is disposed on the front surface of the edge portion of the liquid crystal display panel 2.

The electroconductive cloth 413 is formed into a step shape (substantially L shape) when viewed in section, and includes: a portion 413a that is disposed on the front surface of the edge portion of the liquid crystal display panel 2; and the limit portion 413b that is disposed on the side of the liquid crystal display panel 2.

And, a front surface side hold portion 411a is composed of the sponge member 412 and the portion 413a of the electroconductive cloth 413.

Besides, the electroconductive cloth 413 has a thickness larger than the electroconductive cloths in the first to fourth embodiments, and it is possible to alleviate movement of the liquid crystal display panel 2 in the surface direction (the B direction) by means of the limit portion 413b.

The other structures and effects of the fifth embodiment are the same as the first to fourth embodiments.

### Sixth Embodiment

In this sixth embodiment, with reference to FIG. 14, a case is described, where unlike the first to fifth embodiments, a front surface side hold portion 510a, a limit portion 510b and a rear surface side hold portion 510c of a hold member 510 are formed of the same member.

In the sixth embodiment, as shown in FIG. 14, the hold member 510 is formed of a rubber sheet 511 and an electroconductive cloth 512 disposed on an outer surface of the rubber sheet 511.

The rubber sheet 511 is formed of, for example, a member such as polyurethane rubber, silicone rubber or the like that has a relatively low elastic modulus. Besides, the rubber sheet 511 has a thickness of about 1 mm to about 2 mm, for example. Besides, the rubber sheet 511 is formed into a substantially C shape when viewed in section, and includes: a portion 511a that is disposed on the front surface side of the liquid crystal display panel 2; a portion 511b that is disposed on the side of the liquid crystal display panel 2; and a portion 511c that is disposed on the rear surface side of the liquid crystal display panel 2.

The electroconductive cloth 512, like the rubber sheet 511, is formed into a substantially C shape when viewed in section, and includes: a portion 512a that is disposed on the front surface side of the liquid crystal display panel 2; a portion 512b that is disposed on the side of the liquid crystal display panel 2; and a portion 512c that is disposed on the rear surface side of the liquid crystal display panel 2.

And, the front surface side hold portion 510a, which pushes the front surface of the edge portion of the liquid crystal display panel 2, is composed of the portion 511a of the rubber sheet 511 and the portion 512a of the electroconductive cloth 512. Besides, the limit portion 510b, which limits the liquid crystal display panel 2 moving in the surface direction (the B direction), is composed of the portion 511b of the rubber sheet 511 and the portion 512b of the electroconductive cloth 512. Besides, the rear surface side hold portion 510c, which is biased to the rear surface of the liquid crystal display panel 2, is composed of the portion 511c of the rubber sheet 511 and the portion 512c of the electroconductive cloth 512.

Here, an adhesive layer (not shown) may be disposed between the rubber sheet 511 and the electroconductive cloth 512, and the electroconductive cloth 512 may be bonded to the rubber sheet 511 by means of the adhesive layer. Besides, an adhesive layer (not shown) may be disposed between the hold member 510 and the backlight chassis 3 and between the hold member 510 and the bezel 4, and the hold member 510 may be bonded to the backlight chassis 3 and the bezel 4 by means of the adhesive layer.

The other structures of the sixth embodiment are the same as the first to fifth embodiments.

In the sixth embodiment, as described above, by forming the front surface side hold portion 510a, the limit portion 510b and the rear surface side hold portion 510c of the hold member 510 by means of the same member, it is possible to alleviate the number of components of the hold member 510 increasing.

The other effects of the sixth embodiment are the same as the first to fifth embodiments.

### Seventh Embodiment

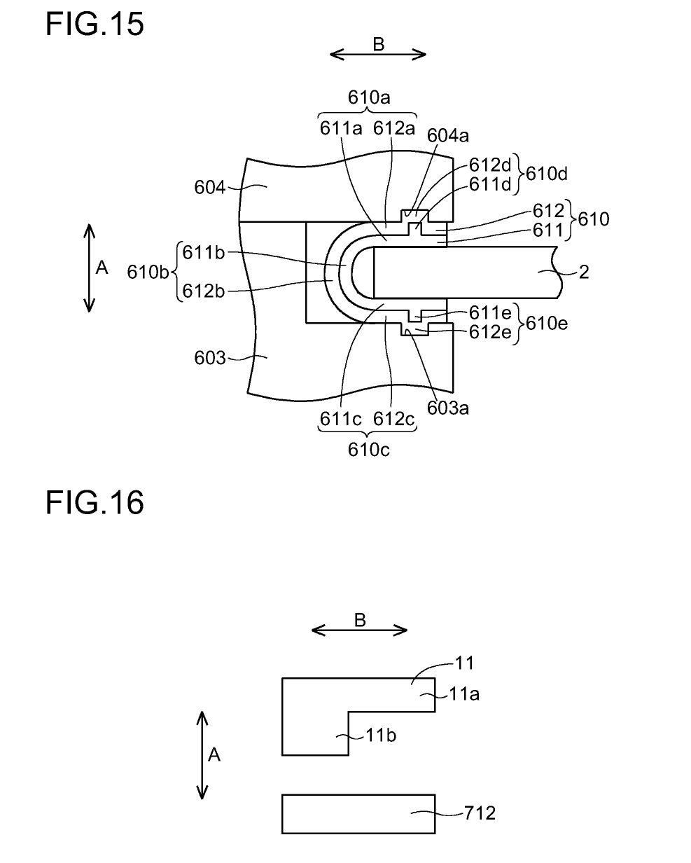

In this seventh embodiment, with reference to FIG. 15, a case is described, where unlike the sixth embodiment, a hold member 610 is provided with protrusions 610d and 610e.

In the seventh embodiment, as shown in FIG. 15, the hold member 610 is formed of a rubber sheet 611 and an electroconductive cloth 612 disposed on an outer surface of the rubber sheet 611.

The rubber sheet 611 includes: a portion 611a that is disposed on the front surface side of the liquid crystal display panel 2; a portion 611b that is disposed on the side of the liquid crystal display panel 2; and a portion 611c that is disposed on the rear surface side of the liquid crystal display panel 2.

The electroconductive cloth 612 includes: a portion 612a that is disposed on the front surface side of the liquid crystal display panel 2; a portion 612b that is disposed on the side of the liquid crystal display panel 2; and a portion 612c that is disposed on the rear surface side of the liquid crystal display panel 2.

And, a front surface side hold portion 610a, which pushes the front surface of the edge portion of the liquid crystal display panel 2, is composed of the portion 611a of the rubber sheet 611 and the portion 612a of the electroconductive cloth 612. Besides, a limit portion 610b, which limits the liquid crystal display panel 2 moving in the surface direction (the B direction), is composed of the portion 611b of the rubber sheet 611 and the portion 612b of the electroconductive cloth 612. Besides, a rear surface side hold portion 610c, which is biased to the rear surface of the liquid crystal display panel 2, is composed of the portion 611c of the rubber sheet 611 and the portion 612c of the electroconductive cloth 612.

Here, in the seventh embodiment, the portion 611a of the rubber sheet 611 is provided with a convex portion 611d that protrudes toward the bezel 604. Because of this, also the portion 612a of the electroconductive cloth 612, which covers the portion 611a of the rubber sheet 611, is provided with a convex portion 612d. And, the protrusion portion 610d is formed of the convex portion 611d of the rubber sheet 611 and the convex portion 612d of the electroconductive cloth 612. Here, the bezel 604 is an example of a “fix member” of the present invention, and the protrusion portion 610d is an example of a “first engagement portion” of the present invention.

Likewise, the portion 611c of the rubber sheet 611 is provided with a convex portion 611e that protrudes toward the backlight chassis 603. Because of this, also the portion 612c of the electroconductive cloth 612, which covers the portion 611c of the rubber sheet 611, is provided with a convex portion 612e. And, the protrusion portion 610e is formed of the convex portion 611e of the rubber sheet 611 and the convex portion 612e of the electroconductive cloth 612. Here, the backlight chassis 603 is an example of the “fix member” of the present invention, and the protrusion portion 610e is an example of the “first engagement portion” of the present invention.

Besides, in the seventh embodiment, the bezel 604 is provided with a concave-shaped engagement portion (concave portion) 604a that engages with the protrusion portion 610d of the hold member 610. Here, the engagement portion 604a is an example of a “second engagement portion” of the present invention.

Besides, the backlight chassis 603 is provided with a concave-shaped engagement portion (concave portion) 603a that engages with the protrusion portion 610e of the hold member 610. Here, the engagement portion 603a is an example of the “second engagement portion” of the present invention.

The other structures of the seventh embodiment are the same as the sixth embodiment.

In the seventh embodiment, as described above, by providing the front surface side hold portion 610a with the protrusion portion 610d and providing the bezel 604 with the engagement portion 604a that engages with the protrusion portion 610d, it is possible to alleviate the hold member 610 moving in the surface direction (the B direction) of the liquid crystal display panel 2. According to this, it is possible to alleviate the liquid crystal display panel 2 moving in the surface direction (the B direction) by means of the hold member 610.

Likewise, by providing the rear surface side hold portion 610c with the protrusion portion 610e and providing the backlight chassis 603 with the engagement portion 603a that engages with the protrusion portion 610e, it is possible to more alleviate the hold member 610 moving in the surface direction (the B direction) of the liquid crystal display panel 2.

The other effects of the seventh embodiment are the same as the sixth embodiment.

Here, it should be considered that the embodiments disclosed this time are examples in all respects and are not limiting. The scope of the present invention is not indicated by the above description of the embodiments but by the claims, and all modifications within the scope of the claims and the meaning equivalent to the claims are covered.

For example, in the above embodiments, the example is described, in which the display panel and the display device are applied to the liquid crystal display panel and the liquid crystal display device; however, the present invention is not limited to this, and may be applied to a display device other than the liquid crystal display device.

Besides, the present invention is applicable to both of a small display device and a large display device; however, the large display panel has many wirings and EMI easily becomes a problem, and a structure for holding a heavy display panel becomes important, accordingly, it is especially effective to apply the present invention to the large display device.

Besides, in the above embodiments, the example is described, in which the liquid crystal display device is formed of the backlight device of direct type; however, the present invention is not limited to this, and the liquid crystal display device may be formed of a backlight device of side-light type. In this case, a light guide plate (light guide member), which guides light from the light source, may be disposed.

Besides, in the above embodiments, the example is described, in which the front surface side hold portion, the limit portion and the rear surface side hold portion have the function to block the electromagnetic wave; however, the present invention is not limited to this, and at least the front surface side hold portion may have the function to block the electromagnetic wave. However, it is preferable that also the limit portion and the rear surface side hold portion have the function to block the electromagnetic wave.

Besides, in the above embodiments, the example is described, in which the sponge member is formed of polyurethane foam; however, the present invention is not limited to this, and the sponge member may be formed of a member other than the polyurethane foam such as rubber, resin and the like, for example.

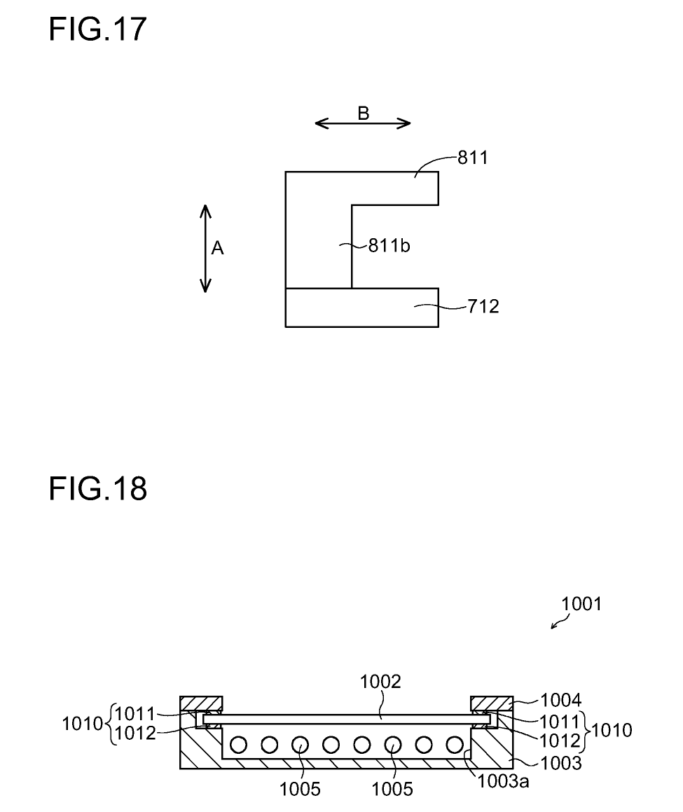

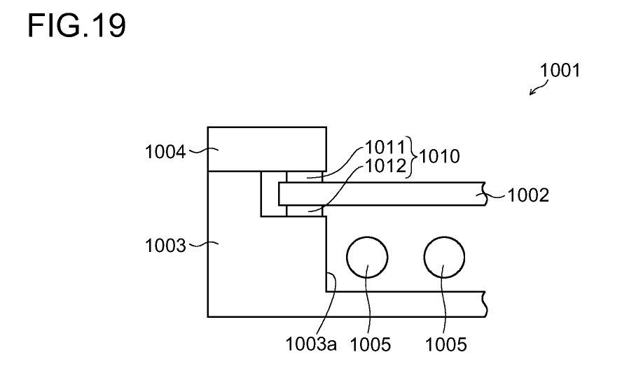

Besides, for example, in the above first embodiment, the example is described, in which both of the push member and the support member are provided with the limit portion; however, the present invention is not limited to this, and either one of the push member and the support member may be provided with the limit portion. For example, as a first modification example of the present invention shown in FIG. 16, a support member (rear surface side hold portion) 712 may be formed into a flat plate shape without providing the limit portion. In this case, for example, as a second modification example shown in FIG. 17, a limit portion 811b of a push member 811 may be formed to come into contact with the support member 712.

Besides, for example, in the above first embodiment, the example is described, in which the push member and the support member are formed of the gasket that includes the sponge member and the electroconductive cloth; however, the present invention is not limited to this, and the push member and the support member may be formed of a material other than the gasket. For example, at least one of the push member and the support member may be formed of an electroconductive cloth, an electromagnetic wave absorption sheet or a metal sheet.

Besides, in the above second embodiment, the example is described, in which the slide stopping member is disposed between the front surface side hold portion of the push member and the liquid crystal display panel; however, the present invention is not limited to this, and the slide stopping member may be disposed between the rear surface side hold portion of the support member and the liquid crystal display panel. Besides, the slide stopping member may be disposed in both spaces between the front surface side hold portion of the push member and the liquid crystal display panel and between the rear surface side hold portion of the support member and the liquid crystal display panel.

Besides, in the above third and fourth embodiments, the example is described, in which each of the push member and the limit member is formed of the sponge member and the electroconductive cloth; however, the present invention is not limited to this, and the push member and the limit member may be formed of two sponge members and one electroconductive cloth that wraps both of the two sponge members.

Besides, in the above fourth embodiment, the example is described, in which to form the sponge member of the limit member to have the elastic modulus higher than the sponge member of the push member, the sponge member of the limit member is formed at the expansion ratio smaller than the sponge member of the push member; however, the present invention is not limited to this, and by forming the sponge member of the limit member and the sponge member of the push member by using materials different from each other, the sponge member of the limit member may be formed to have the elastic modulus higher than the sponge member of the push member.

Besides, in the above seventh embodiment, the example is described, in which the hold member is provided with the protrusion portion, and the bezel and the backlight chassis are provided with the engagement portion (the concave portion); however, the present invention is not limited to this, and the bezel and the backlight chassis may be provided with the protrusion portion, and the hold member may be provided with the engagement portion (the concave portion). Besides, only either one of the bezel and the backlight chassis may be provided with the engagement portion and the protrusion portion.

### REFERENCE SIGNS LIST

1 liquid crystal display device (display device)
2 liquid crystal display panel (display panel)
10, 210, 310, 510, 610 hold member
11a, 411a, 510a, 610a front surface side hold portion
11b, 12b, 413b, 510b, 610b, 811b limit portion
12a, 510c, 610c rear surface side hold portion
20 slide stopping member
111, 121, 412 sponge member
112, 122, 311b, 312b, 413, 512, 612 electroconductive cloth
211, 311 push member (front surface side hold portion)
212, 312 limit member (limit portion)
311a sponge member (first sponge member)
312a sponge member (second sponge member)
603 backlight chassis (fix member)
603a, 604a engagement portion (second engagement portion)
604 bezel (fix member)
610d, 610e protrusion portion (first engagement portion)
712 support member (rear surface side hold portion)

1. A display device comprising:
a display panel; and
a hold member that holds an edge portion of the display panel; wherein
the hold member includes:
a front surface side hold portion that is disposed on a front surface side of the display panel;
a rear surface side hold portion that is disposed on a rear surface side of the display panel; and
a limit portion that is disposed on a side of the display panel and limits the display panel moving in a surface direction of the display panel, and
at least the front surface side hold portion has a function to block an electromagnetic wave.

2. The display device according to claim 1, wherein
the limit portion also has the function to block the electromagnetic wave.

3. The display device according to claim 1, wherein
the rear surface side hold portion also has the function to block the electromagnetic wave.

4. The display device according to claim 1, wherein
the hold member includes an electroconductive cloth.

5. The display device according to claim 1, wherein
the limit portion is integrally formed with the front surface side hold portion.

6. The display device according to claim 1, wherein
the hold member includes a sponge member and an electroconductive cloth that covers the sponge member.

7. The display device according to claim 6, wherein
the sponge member includes a first sponge member and a second sponge member that has an elastic modulus higher than the first sponge member;
the front surface side hold portion is formed of the first sponge member; and
the limit portion is formed of the second sponge member.

8. The display device according to claim 1, comprising
a slide stopping member that is disposed between at least one of the front surface side hold portion and the rear surface side hold portion and the display panel, and alleviates the display panel moving in the surface direction.

9. The display device according to claim 8, wherein
the slide stopping member is formed of PORON (registered trademark).

10. The display device according to claim 1, further comprising
a fix member that fixes at least one of the front surface side hold portion and the rear surface side hold portion;
at least one of the front surface side hold portion and the rear surface side hold portion is provided with a first engagement portion; and
the fix member is provided with a second engagement portion that engages with the first engagement portion, and alleviates the hold member moving in the surface direction.
